(19) United States
(12) Patent Application Publication
(10) Pub. No.: US 2025/0040422 A1
(43) Pub. Date: Jan. 30, 2025

(54) QUANTUM DOT LUMINESCENT MATERIAL, QUANTUM DOT PATTERNING METHOD, QUANTUM DOT FILM AND DISPLAY DEVICE

(71) Applicant: Yungu (Gu’an) Technology Co., Ltd., Langfang (CN)

(72) Inventors: Fuxing JIAO, Langfang (CN); Zhimin YAN, Langfang (CN); Liang SU, Langfang (CN); Fengjie JIN, Langfang (CN)

(73) Assignee: Yungu (Gu’an) Technology Co., Ltd., Langfang (CN)

(21) Appl. No.: 18/916,897

(22) Filed: Oct. 16, 2024

(30) Foreign Application Priority Data
Oct. 30, 2023 (CN) 202311423243.1

(51) Int. Cl. H10K 85/10; B82Y 20/00; B82Y 40/00; C09K 11/02; H10K 50/115; H10K 71/20; H10K 85/30; H10K 101/30

(52) U.S. Cl. CPC H10K 85/10; C09K 11/025; H10K 85/30; B82Y 20/00; B82Y 40/00; H10K 50/115; H10K 71/211; H10K 2101/30

(57) ABSTRACT

A quantum dot luminescent material, a quantum dot patterning method, a quantum dot film, and a display device. The quantum dot luminescent material includes a plurality of quantum dots; a plurality of ligands attached to the quantum dots; a plurality of crosslinking reactants configured to undergo a crosslinking reaction to connect at least two of the quantum dots and the crosslinking reactants being a plurality of crosslinking molecules or a plurality of crosslinking groups; wherein the quantum dots and the crosslinking reactants satisfy at least one of Condition (1), Condition (2), or a combination thereof: Condition (1): the crosslinking reactants have a lowest unoccupied molecular orbital (LUMO) energy level that is located outside a bandgap of the quantum dots; and Condition (2): the crosslinking reactants have a highest occupied molecular orbital (HOMO) energy level that is located outside the bandgap of the quantum dots.

### CROSS REFERENCE TO RELATED APPLICATION

This application claims priority to the Chinese Patent Application No. 202311423243.1, filed on Oct. 30, 2023, which is incorporated herein by reference in its entirety.

### TECHNICAL FIELD

The present application belongs to the field of display technology, and particularly relates to a quantum dot luminescent material, a quantum dot patterning method, a quantum dot film, and a display device.

### BACKGROUND

As quantum dots (QDs) have a size-dependent luminescence, narrow half-peak wave width, high photoluminescence efficiency, and thermal stability, a quantum dot light emitting diode (QLED) with the quantum dots as a luminescence center has become a highly promising next-generation light emitting device.

However, the luminescence performance of a quantum dot luminescent layer with such quantum dots is to be improved.

### SUMMARY

It is an object of the present application to provide a quantum dot luminescent material, a quantum dot patterning method, a quantum dot film, and a display device, aiming at solving the problem that the luminescent performance of a quantum dot luminescent layer having quantum dots is to be improved.

A first aspect of the present application provides a quantum dot luminescent material, the quantum dot luminescent material comprising
a plurality of quantum dots;
a plurality of ligands, the ligands attached to the quantum dot;
a plurality of crosslinking reactants, the crosslinking reactants configured to undergo a crosslinking reaction to connect at least two of the quantum dots and the crosslinking reactants being crosslinking molecules or crosslinking groups;
wherein the quantum dots and the crosslinking reactants satisfy at least one of the following:
the crosslinking reactants have a lowest unoccupied molecular orbital (LUMO) energy level that is located outside a bandgap of the quantum dots; and
the crosslinking reactants have a highest occupied molecular orbital (HOMO) energy level that is located outside the bandgap of the quantum dots.

In some embodiments, the quantum dots have a valence band greater than the HOMO energy level of the crosslinking reactants, and a difference in energy level between the valence band of the quantum dots and the HOMO energy level of the crosslinking reactants is greater than 0.2 eV.

In some embodiments, the quantum dots have a conduction band less than the LUMO energy level of the crosslinking reactants, and a difference in energy level between the conduction band of the quantum dots and the LUMO energy level of the crosslinking reactants is greater than 0.2 eV.

In some embodiments, the crosslinking reactants are a crosslinking molecule, the crosslinking molecule comprises at least two photosensitive groups, and the photosensitive groups are configured to undergo a photocrosslinking reaction with a reactive group of the ligands.

In some embodiments, n photosensitive groups are provided for one crosslinking reactant in which 2≤n≤6.

In some embodiments, the crosslinking molecule has a structure shown in Formula (1):

P—R—P (1),

wherein P is a photosensitive group.

In some embodiments, R is an aliphatic group, a heterocyclic group or an aromatic group comprising a benzene ring structure.

In some embodiments, R comprises at least one halogen element.

In some embodiments, R comprises at least one alkali metal element.

In some embodiments, the crosslinking molecule has one of the structure shown in formula (2), the structure shown in formula (3), the structure shown in formula (4), or the structure shown in formula (5) below:

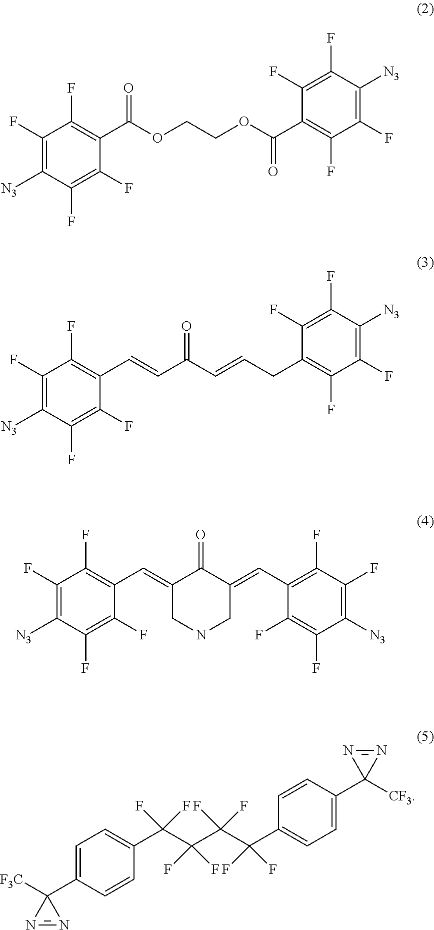 [SMILES: [N-]=[N+]=Nc1c(F)c(F)c(C(=O)OCCOC(=O)c2c(F)c(F)c(N=[N+]=[N-])c(F)c2F)c(F)c1F ; [N-]=[N+]=Nc1c(F)c(F)c(/C=C/C(=O)/C=C/Cc2c(F)c(F)c(N=[N+]=[N-])c(F)c2F)c(F)c1F ; [N-]=[N+]=Nc1c(F)c(F)c(/C=C2\CNC/C(=C\c3c(F)c(F)c(N=[N+]=[N-])c(F)c3F)C2=O)c(F)c1F ; FC(F)(F)C1(c2ccc(C(F)(F)C(F)(F)C(F)(F)C(F)(F)c3ccc(C4(C(F)(F)F)N=N4)cc3)cc2)N=N1]

In some embodiments, the crosslinking reactants are a crosslinking group attached to the ligands, and the crosslinking group is configured to undergo a photo-crosslinking reaction with a reactive group of the ligands.

In some embodiments, the plurality of ligands comprises a first ligand and a second ligand, the first ligand and the second ligand are attached to one quantum dot via coordination, the first ligand is connected to the crosslinking group, and the crosslinking group is configured to undergo a photo-crosslinking reaction with a reactive group of the second ligand.

In some embodiments, the plurality of quantum dots comprises a first quantum dot and a second quantum dot, the plurality of ligands comprises a first ligand and a second ligand, the first ligand is attached to the first quantum dot via coordination, the second ligand is attached to the second quantum dot via coordination, the crosslinking group is attached to the first ligand, and the crosslinking group is configured to undergo a photocrosslinking reaction with the second ligand.

In some embodiments, the quantum dots is any one of red light quantum dots, green light quantum dots, and blue light quantum dots.

In some embodiments, in the quantum dot luminescent material, a mass ratio of quantum dots and the crosslinking reactants is in the range of 1% to 10%.

In some embodiments, the quantum dots are a red light quantum dot, and in the quantum dot luminescent material, a mass ratio of the red light quantum dots and the crosslinking reactants is in the range of 1% to 6%.

In some embodiments, the quantum dots are a green light quantum dot, and in the quantum dot luminescent material, a mass ratio of the green light quantum dots and the crosslinking reactants is in the range of 1% to 8%.

In some embodiments, the quantum dots are a blue light quantum dot, and in the quantum dot luminescent material, a mass ratio of the blue light quantum dots and the crosslinking reactants is in the range of 1% to 8%.

A second aspect of the present application provides a quantum dot patterning method comprising:
forming a first material layer on a first interface layer with the quantum dot luminescent material as provided in the first aspect, the first material layer comprising a first region and a second region;
exposing the first region to cause the crosslinking reactant to undergo a photocrosslinking reaction to connect at least two quantum dots;
developing the first material layer to remove a portion of the first material layer disposed in the second region, thereby obtaining a patterned first quantum dot luminescent layer.

In some embodiments, the method further comprises:
forming a second material layer on the first interface layer with the quantum dot luminescent material as provided in the first aspect, wherein the second material layer comprises quantum dots configured to emit a second color light, and the first material layer comprises quantum dots configured to emit a first color light, and the second material layer comprises a third region and a fourth region;
exposing the third region to cause the crosslinking reactant to undergo a photo-crosslinking reaction to connect at least two quantum dots;
developing the second material layer to remove a portion of the second material layer disposed in the fourth region, thereby obtaining a patterned second quantum dot luminescent layer, the first quantum dot luminescent layer and the second quantum dot luminescent layer being parallel-disposed on the first interface layer.

A third aspect of the present application provides a quantum dot film comprising a first quantum dot luminescent layer and a second quantum dot luminescent layer, the first quantum dot luminescent layer configured to emit a first color light and adopt the above-mentioned quantum dot luminescent material, and the secondquantum dot luminescent layer configured to emit a second color light.

A fourth aspect of the present application provides a display device characterized in that it comprises a quantum dot film as provided in the third aspect.

In some embodiments, a light emitting device comprises
a bottom electrode;
a first carrier transport layer, disposed on a side of the bottom electrode;
a second carrier transport layer, disposed on a side of the first carrier transport layer away from the bottom electrode;
a top electrode, disposed on the side of the second carrier transport layer away from the bottom electrode; and
a quantum dot film, disposed between the first carrier transport layer and the second carrier transport layer.

The quantum dot luminescent material, the quantum dot patterning method, the quantum dot film, and the display device according to embodiments of the present application improve stability of the plurality of quantum dots by setting crosslinking reactants in the quantum dot luminescent material so that the crosslinking reactants can undergo a cross-linking reaction to connect at least two quantum dots, thereby forming a lattice structure; and may, to a certain extent, reduce or avoid transfer of photogenerated carriers generated by excitation of the quantum dots to the crosslinking reactant, reduce a decrease in photoluminescence quantum yield, improve the luminescence performance of a quantum dot luminescent layer prepared from the quantum dot luminescent material, and improve the luminescence performance of a display device adopting the quantum dot luminescent layer, by setting the crosslinking reactants to have a lowest unoccupied molecular orbital (LUMO) energy level that is located outside a bandgap of the quantum dots; and the crosslinking reactants to have a highest occupied molecular orbital (HOMO) energy level that is located outside the bandgap of the quantum dots.

### DESCRIPTION OF THE DRAWINGS

In order to more clearly illustrate the technical solution of embodiments of the present application, the accompanying drawings to be used in the embodiments of the present application will be briefly introduced below, and it is apparent that the accompanying drawings described below are only some embodiments of the present application, and that for those skilled in the field, other accompanying drawings can be obtained based on the accompanying drawings without creative labor.

FIG. 1 is a schematic diagram showing the structure of a quantum dot luminescent material provided by embodiments of the present application;

FIG. 2 shows a schematic diagram showing the crosslinking principle of a quantum dot luminescent material provided by embodiments of the present application;

FIG. 3 is a schematic diagram showing the crosslinking principle of a quantum dot luminescent material provided by embodiments of the present application;

FIG. 4 is a schematic diagram comparing energy levels of a quantum dot and a crosslinking reactant provided by embodiments of the present application;

FIG. 5 is a schematic diagram comparing energy levels of a quantum dot and a crosslinking reactant provided by embodiments of the present application;

FIG. 6 is a schematic diagram comparing energy levels of a quantum dot and a crosslinking reactant provided by embodiments of the present application;

FIG. 7 is a schematic diagram comparing energy levels of quantum dots and a plurality of crosslinking reactants provided by embodiments of the present application;

FIG. 8 shows a schematic diagram for preparing a first quantum dot luminescent layer provided by embodiments of the present application;

FIG. 9 shows a schematic diagram for preparing a second quantum dot luminescent layer provided by embodiments of the present application;

FIG. 10 is a schematic diagram showing the structure of a display device provided by embodiments of the present application.

The accompanying drawings are marked as follows: 1—quantum dots; 2—ligands; 3—linking reactants; 100—quantum dot film; 11—bottom electrode; 12—first carrier transport layer; 13—second carrier transport layer; 14—top electrode; 15—substrate; 16—first carrier injection layer; 17—second carrier injection layer.

### DETAILED DESCRIPTION

Embodiments of the present application will be described in details below in conjunction with the accompanying drawings and particular embodiments. The detailed description of the following embodiments and the accompanying drawings are used to exemplarily illustrate the principles of the present application, but cannot be used to limit the scope of the present application, i.e., the present application is not limited to the described embodiments.

In the description of the present application, it is to be noted that, unless otherwise indicated, ‘plurality’ means more than two; the terms ‘on’, ‘under’, ‘left,’ “right,” “inside,” “outside,” and the like indicate orientation or positional relationships, which are only for the purpose of facilitating the description of the present application and simplifying the description, and are not intended to indicate or imply that the device or element referred to must have a particular orientation, be constructed and operated in a particular orientation, and therefore are not to be construed as limiting the present application. In addition, the terms ‘first’, ‘second’, ‘third’, etc. are used for descriptive purposes only and are not to be construed as indicating or implying relative importance. The term ‘perpendicular’ is not perpendicular in the strict sense, but within the tolerance of error. ‘Parallel’ is not parallel in the strict sense, but within the tolerance of error.

Reference to ‘embodiments’ in the application means that particular features, structures or characteristics described in connection with the embodiments may be included in at least one embodiment of the present application. The phrase present at various points in the specification does not necessarily refer to the same embodiment, nor is it a separate or alternative embodiment that is mutually exclusive of other embodiments. It is understood by those skilled in the art, both explicitly and implicitly, that the embodiments described in this application may be combined with other embodiments.

The wording of orientation appearing in the following description are in the directions shown in the drawings and are not intended to limit the specific structure of the present application. In the description of the present application, it should also be noted that, unless otherwise expressly provided and limited, the terms ‘mounted’, ‘connected’, ‘attached’ are to be understood broadly. For example, it may be a fixed connection, or it may be a connectable connection, or it may be a fixed connection. For example, they may be fixed, removable, or integrally connected; or they may be directly connected, or indirectly connected through an intermediate medium. Those skilled in the art may understand the specific meaning of the above terms in the present application on a case-by-case basis.

Quantum dots, also known as semiconductor nanocrystals, are a new type of semiconductor nanomaterial. They have unique photo-luminescent and electro-luminescent properties due to their quantum size effect and dielectric confinement effect. Compared with traditional organic fluorescent dyes, quantum dots have excellent optical properties such as high quantum yield, high photochemical stability, lack of photolysis, as well as wide excitation, narrow emission, high color purity, and size-dependent luminescence color. At present, a quantum dot luminescent layer may be formed by a direct lithography process. In the process of preparing the quantum dot luminescent layer by the direct lithography process, some of the quantum dots may be crosslinked by crosslinking reactants, so that the crosslinked quantum dots can be retained, and the uncrosslinked quantum dots can be peeled off, thereby obtaining a patterned quantum dot luminescent layer. In the quantum dot luminescent layer, the crosslinking reactants are prone to cause photogenerated carrier transfer, resulting in a decrease in the photoluminescence quantum yield (PLQY) of the quantum dot luminescent layer and affecting the luminescent performance of the quantum dot luminescent layer.

In order to solve the above problem, embodiments of the present application provide a quantum dot luminescent material, a quantum dot patterning method, a quantum dot film, and a display device. Embodiments of the quantum dot luminescent material, the quantum dot patterning method, the quantum dot film, and the display device each are described hereinafter in conjunction with the accompanying drawings.

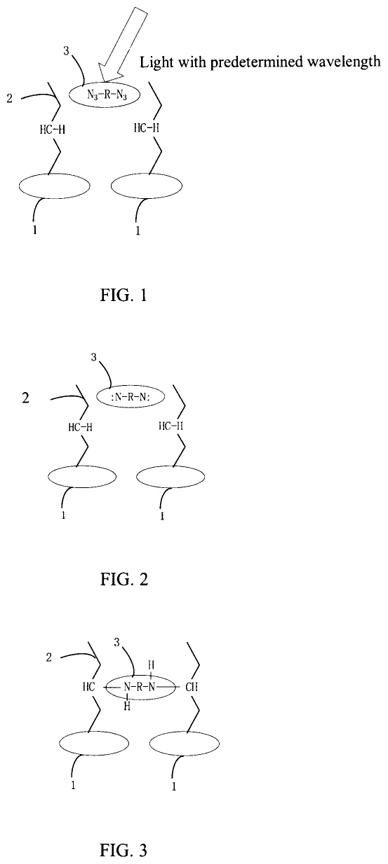

With reference to FIGS. 1, 2 and 3, a first aspect of the present application provides a quantum dot luminescent material. The quantum dot luminescent material comprises a plurality of quantum dots 1, a plurality of ligands 2 and a plurality of crosslinking reactants 3, the ligands 2 are attached to the quantum dots 1; the crosslinking reactants 3 are configured to undergo a cross-linking reaction to connect at least two quantum dots 1, and the crosslinking reactants 3 are cross-linking molecules or cross-linking groups.

The quantum dots 1 and the crosslinking reactants 3 satisfy at least one of the following conditions:
(1) the crosslinking reactants 3 have a lowest unoccupied molecular orbital (LUMO) energy level that is located outside a bandgap of the quantum dots 1; and
(2) the crosslinking reactants 3 have a highest occupied molecular orbital (HOMO) energy level that is located outside the bandgap of the quantum dots 1.

The quantum dot luminescent material can be used to prepare a quantum dot luminescent layer in a display device. Quantum dots 1 (QDs) are a semiconductor nanocrystal with a radius less than or close to Bohr radius of excitons and are a zero-dimensional nanomaterial. Quantum dots 1 can be excited to generate fluorescence, and quantum dots 1 of different sizes may emit different colors. Therefore, the patterned quantum dot luminescent layer prepared by the quantum dot luminescent material may be used to display images.

The quantum dots 1 may be nano-sized inorganic nanoparticles. The ligands 2 may attached on the surface of the quantum dots 1, and the ligands 2 may provide colloidal stability for the quantum dots 1. The physical and chemical properties such as photoelectricity and magnetism of the quantum dots 1 attached with the ligands 2 are mainly determined by their inorganic cores, i.e., by the quantum dots 1. The processability of the quantum dots 1 attached with the ligands 2 is mainly determined by the ligands 2, so that the quantum dots 1 attached with the ligands 2 may form a complex structure. Therefore, those skilled in the art can select the quantum dots 1 attached with the ligands 2 via coordination with different physical and chemical properties as needed, so that the quantum dots 1 attached with the ligands 2 have different properties.

The quantum dots 1 can be selected from: II-VI group quantum dots, such as CdS, CdSe, CdTe, ZnS, ZnSc, ZnTe, HgSc, HgTe, HgS, HgₓCd₁₋ₓTe, HgₓCd₁₋ₓS, HgₓCd₁₋ₓSe, HgₓZn₁₋ₓTe, CdₓZn₁₋ₓSe, or CdₓZn₁₋ₓS, where 0<x<1; or III-V group quantum dots 1, such as InP, InAs, InSb, GaAs, GaP, GaN, GaSb, InN, InSb, AlP, AlN, or AlAs; or VI-VI group quantum dots, such as PbS, PbSe, or PbTe; or quantum dots with a core-shell structure, including CdSc@ZnS, CdSe@CdS, InP@ZnS, CdTe@CdSe, CdSc@ZnTe, ZnTe@CdSc, ZnSc@CdS or Cd₁₋ₓZnₓS@ZnS; or ABX3 type perovskite quantum dots 1, where A is one or more of CH₃NH₃+ (methylamine), NH₂CH═NH₂ (formamidine), and Cs+, B is one or two of Pb²⁺ and Sn²⁺, and X is one or more of Cl−, Br−, and I−, including CH₃NH₃PbBr₃, CH₃NH₃PbCl₃, CH₃NH₃PbI₃, CsPbBr₃, CsPbCl₃, and CsPbI₃; or other quantum dots, such as CuInS₂, CuInSc₂, AgInS₂, and the like.

A crosslinking reaction is a reaction in which two or more molecules are bonded and crosslinked to each other to form a lattice structure. The crosslinking reactants 3 may connect at least two quantum dots 1 by undergoing a crosslinking reaction to improve the stability of the plurality of quantum dots 1. In embodiments of the present application the crosslinking reactants 3 are a crosslinking molecule or a crosslinking group. The crosslinking reactants 3 may be a reactant containing a carbon-carbon unsaturated bond, an isocyanate-based reactant, a bis-azide-based reactant, a ketone group-containing reactant, a halogen-containing Lewis acid, a halogen-containing Lewis base, and the like. Optionally, the crosslinking reactant 3 may be benzophenone and derivatives thereof.

With reference to FIG. 1, in the case where the crosslinking reactant 3 is a crosslinking molecule, the crosslinking molecule is mixed with the quantum dots 1. With reference to FIG. 2, under the desired reaction conditions for the crosslinking reaction, the crosslinking reaction occurs by irradiating the crosslinking molecule at a predetermined wavelength of light waves so as to stimulate the crosslinking molecule as shown in FIG. 2. With reference to FIG. 3, the crosslinking molecule undergoes a crosslinking reaction to connect at least two quantum dots 1, and the plurality of quantum dots 1 form a lattice structure under the connection of the plurality of crosslinking molecules. In the case where the crosslinking reactant 3 is a crosslinking group, the crosslinking group may be attached to the quantum dots 1 by chemical bonding via coordination, and under the desired reaction conditions for the crosslinking reaction, the crosslinking group undergoes a cross-linking reaction to connect at least two quantum dots 1 and a lattice structure is formed from the plurality of quantum dots 1.

The quantum dot luminescent material may be formed into a quantum dot luminescent layer by a direct lithography process. For example, the quantum dot luminescent material is first used to form a material layer, and the material layer is subjected to an exposure process at its target region using a mask plate having an opening to enable the quantum dots 1 in the target region to undergo a photo-crosslinking reaction with the crosslinking reactant 3, and the quantum dots 1 in the target region form a lattice structure, so that the material layer in the target region has a stability higher than the material layer in a non-target region. The material layer is developed to remove the material layer in the non-target region to obtain a patterned quantum dot luminescent layer. The quantum dots 1 in the quantum dot luminescent layer upon excitation by light generates photogenerated carriers, i.e., electrons and holes, the electrons and holes are recombine to emit photons, and the quantum dot luminescent layer emits a color light dependent on the size of the quantum dots 1.

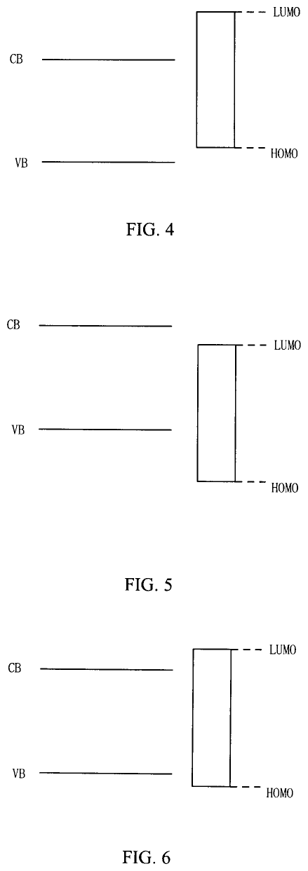

For a semiconductor material, its energy band with the highest energy that is filled with electrons is called a valence band; its energy band with the lowest energy that is not filled with electrons is called a conduction band, and the energy difference between the minimum energy level of the conduction band and the maximum energy level of the valence band is called a bandgap. For an organic material, it has frontier molecular orbitals, the energy levels of which comprise the highest occupied molecular orbital (Highest Occupied Molecular Orbital, HOMO) energy level and the lowest unoccupied molecular orbital (Lowest Unoccupied Molecular Orbital, LUMO) energy level. In the present application, the situation that the energy level of frontier molecular orbitals of the crosslinking reactants 3 is located outside a bandgap of quantum dots 1, includes the following cases:
(1) As shown in FIG. 4, the lowest unoccupied molecular orbital LUMO energy level of the crosslinking reactants 3 is located outside the bandgap of quantum dots 1, and the highest occupied molecular orbital HOMO energy level of the crosslinking reactant 3 is located within the bandgap of quantum dots 1;
(2) As shown in FIG. 5, the lowest unoccupied molecular orbital LUMO energy level of the crosslinking reactants 3 is located within the range of the bandgap of quantum dots 1, and the highest occupied molecular orbital HOMO energy level of the crosslinking reactants 3 is located outside the bandgap of quantum dots 1;
(3) As shown in FIG. 6, the lowest unoccupied molecular orbital LUMO energy level of the crosslinking reactant 3 is located outside the range of the bandgap of quantum dots 1, and the highest occupied molecular orbital HOMO energy level of the crosslinking reactants 3 is located outside the range of the bandgap of quantum dots 1.

By setting the lowest unoccupied molecular orbital LUMO energy level of the crosslinking reactants 3 to be located outside the bandgap of the quantum dots 1, or the highest occupied molecular orbital HOMO energy level of the crosslinking reactants 3 to be located outside the bandgap of the quantum dots 1, it is possible, to a certain extent, to reduce or avoid the transfer of photogenerated carriers generated by excitation of the quantum dots 1 to the crosslinking reactants 3, and to reduce a decrease in the photoluminescence quantum yield (PLQY), and to improve the luminescence performance of the quantum dot luminescent layer prepared from the quantum dot luminescent material. Optionally, the HOMO energy level and the LUMO energy level of the crosslinking reactants 3 may be determined using a solution electrochemistry.

In embodiments of the present application, stability of the plurality of quantum dots 1 is improved by providing crosslinking reactants 3 in the quantum dot luminescent material so that the crosslinking reactants 3 can undergo a crosslinking reaction to connect at least two quantum dots 1 to form a lattice structure; by setting the lowest unoccupied molecular orbital LUMO energy level of the crosslinking reactants 3 to be located outside the bandgap of the quantum dots 1, or the highest occupied molecular orbital HOMO energy level of the crosslinking reactants 3 to be located outside the bandgap of the quantum dots 1, it is possible, to a certain extent, to reduce or avoid transfer of photogenerated carriers generated by excitation of the quantum dots 1 to the crosslinking reactants 3, and to reduce a decrease in the photoluminescence quantum yield (PLQY), and to improve the luminescence performance of the quantum dot luminescent layer prepared from the quantum dot luminescent material.

In some embodiments, the quantum dots 1 have a valence band greater than the HOMO energy level of the crosslinking reactants 3, and a difference in energy level between the valence band of the quantum dots 1 and the HOMO energy level of the crosslinking reactants 3 is greater than 0.2 eV.

The valence band of the quantum dots 1 is larger than the HOMO energy level of the crosslinking reactants 3, which means that the HOMO energy level of the crosslinking reactants 3 is more negative than the valence band of the quantum dots 1. In the quantum dot luminescent layer formed from the quantum dot luminescent material, by setting the valence band of the quantum dots 1 is larger than the HOMO energy level of the crosslinking reactants 3, it is possible, to a certain extent, to reduce or avoid transfer of photogenerated carriers at the valence band to the crosslinking reactants 3 in which the photogenerated carriers at the valence band may be holes generated by the excitation of the quantum dots 1. By setting the difference in energy level between the valence band of the quantum dots 1 and the HOMO energy level of the crosslinking reactants 3 is greater than 0.2 eV, the transfer of photogenerated carriers at the valence band to the crosslinking reactants 3 may be effectively reduced or avoided.

In the case where the valence band of the quantum dots 1 is smaller than the HOMO energy level of the selected crosslinking reactants, the HOMO energy level of the crosslinking reactants can be reduced by decreasing ionisation energy of the crosslinking reactants. For example, a chemical element with a higher ionisation energy is provided in the crosslinking reactants 3.

In some embodiments, the conduction band of the quantum dots 1 is smaller than the LUMO energy level of the crosslinking reactants 3, and a difference in energy level between the conduction band of the quantum dots 1 and the LUMO energy level of the crosslinking reactants 3 is greater than 0.2 eV.

The conduction band of the quantum dots 1 is smaller than the LUMO energy level of the crosslinking reactants 3, which means that the LUMO energy level of the crosslinking reactants 3 is less negative than the conduction band of the quantum dots 1. In the quantum dot luminescent layer formed from the quantum dot luminescent material, by setting the conduction band of the quantum dots 1 is smaller than the LUMO energy level of the crosslinking reactants 3, it is possible, to a certain extent, to reduce or avoid transfer of photogenerated carriers at the conduction band to the crosslinking reactants 3 in which the photogenerated carriers at the conduction band may be electrons generated by the excitation of the quantum dots 1. By setting the difference in energy level between the conduction band of the quantum dots 1 and the HOMO energy level of the crosslinking reactants 3 is greater than 0.2 eV, the transfer of photogenerated carriers at the conduction band to the crosslinking reactants 3 may be effectively reduced or avoided.

In the case where the conduction band of the quantum dots 1 is larger than the LUMO energy level of the selected crosslinking reactants, the LUMO energy level of the crosslinking reactants can be enhanced by decreasing the affinity energy of the crosslinking reactants. For example, a chemical element with a larger atomic radius is provided in the crosslinking reactants 3.

In some embodiments, the crosslinking reactants 3 are a crosslinking molecule, the crosslinking molecule comprises at least two photosensitive groups, and the photosensitive groups are configured to undergo a photo-crosslinking reaction with a reactive group of the ligands 2.

The coordination functional group in the ligands 2 that coordinate with the quantum dots 1 may be selected from carboxyl (—COOH), sulfonic acid (—SO₃H), hydroxyl (—OH), sulfhydryl (—SH), amino (—NH₂), and the like, without being limited thereto. In addition, one ligand 2 may comprise one or more coordination functional groups, for example, 1, 2, 3 coordination functional groups, the coordination functional groups being each independently selected from the aforementioned groups. Of n ligands 2 connected to the same quantum dot 1 via coordination, all of the n ligands 2 may comprise a reactive group capable of undergoing a photo-crosslinking reaction with the photosensitive groups, or some of the n ligands 2 may comprise a reactive group capable of undergoing a photo-crosslinking reaction with the photosensitive groups.

The photo-crosslinking reaction is a crosslinking reaction during which the reactants absorb light energy. The crosslinking molecule comprises at least two photosensitive groups, where one of the photosensitive groups in the crosslinking molecule undergoes a photo-crosslinking reaction with one active group of the ligands 2. Accordingly, the n photosensitive groups in the crosslinking molecule may be link with a reactive group of the n ligands 2 so that the plurality of quantum dots 1 form a lattice structure by crosslinking of the photosensitive groups with the reactive groups. The photosensitive groups in the crosslinking molecule may be the same functional group or different functional groups.

In some embodiments, n photosensitive groups are provided for one crosslinking reactant 3, in which 2≤n≤6.

The n photosensitive groups each may undergo a photo-crosslinking reaction with a reactive group of the ligands 2 one by one to form n crosslinked photosensitive group-active group. In the case where the n photosensitive groups undergo a photo-crosslinking reaction with a reactive group of the n quantum dots 1 respectively, one crosslinking reactant 3 can be linked with n quantum dots 1. For example, in the case where one crosslinking reactant 3 has 6 photosensitive groups, the crosslinking reactant 3 can be linked with at most 6 quantum dots 1 by a photo-crosslinking reaction. The crosslinking efficiency may be improved by increasing the number of the photosensitive groups in one crosslinking reactant 3. Those skilled in the art may provide a desired number of photosensitive groups in one crosslinking reactant 3 as desired.

In some embodiments, the crosslinking molecule has the structure shown in the following formula (1):

P—R—P (1),

wherein P is a photosensitive group.

The two photosensitive groups P attached to the R group each are capable of undergoing a photo-crosslinking reaction with two reactive groups, thereby allowing the two quantum dots to be linked together.

In some embodiments, R is an aliphatic group, a heterocyclic group or an aromatic group comprising a benzene ring structure, thereby improving the stability of the crosslinking molecule itself.

In some embodiments, R comprises at least one halogen element.

Chemical elements located in the same period from left to right have a gradually increased ionization energy. Thus, it is possible to increase the ionisation energy of the crosslinking molecule by incorporating a halogen element into R to enhance the HOMO energy level of the crosslinking reactant. One or more halogen elements may be incorporated into R in which the halogen element in R may be a halogen group.

In some embodiments, R comprises at least one alkali metal element.

It is possible to decrease the ionisation energy of the crosslinking molecule by incorporating an alkali metal element into R to reduce the HOMO energy level of the crosslinking reactant. One or more alkali metal elements may be incorporated into R in which the alkali metal element in R may be an alkali metal group.

In some embodiments, the crosslinking molecule has one of the structure shown in formula (2), the structure shown in formula (3), the structure shown in formula (4), or the structure shown in formula (5) below:

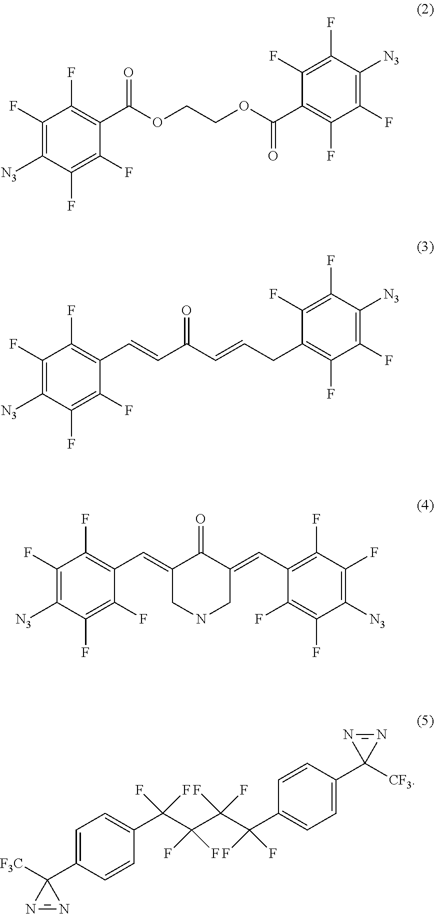 [SMILES: [N-]=[N+]=Nc1c(F)c(F)c(C(=O)OCCOC(=O)c2c(F)c(F)c(N=[N+]=[N-])c(F)c2F)c(F)c1F ; [N-]=[N+]=Nc1c(F)c(F)c(/C=C/C(=O)/C=C/Cc2c(F)c(F)c(N=[N+]=[N-])c(F)c2F)c(F)c1F ; [N-]=[N+]=Nc1c(F)c(F)c(/C=C2\CNC/C(=C\c3c(F)c(F)c(N=[N+]=[N-])c(F)c3F)C2=O)c(F)c1F ; FC(F)(F)C1(c2ccc(C(F)(F)C(F)(F)C(F)(F)C(F)(F)c3ccc(C4(C(F)(F)F)N=N4)cc3)cc2)N=N1]

The crosslinking molecule shown in formulae (2), (3) and (4) may connect two reactive groups through 2 —N3 groups, respectively. The crosslinking molecule shown in formula (5) may connect two reactive groups through 2 diazo groups.

In some embodiments, the crosslinking reactant 3 is a crosslinking group attached to the ligands 2, and the crosslinking group is configured to undergo a photo-crosslinking reaction with an active group of the ligands 2.

A plurality of ligands 2 may coordinate with one quantum dot 1 via coordination, and one or more crosslinking groups may be attached to one ligand. Thus the quantum dot 1 may connect a plurality of crosslinking groups through the ligand 2 as desired. The crosslinking groups attached to the same quantum dot 1 may be different, and the crosslinking groups attached to the same ligand 2 may also be different. Thus, those skilled in the art may select different cross-linking groups and a suitable number of cross-linking groups to be connected to the same quantum dot 1 as needed.

In some embodiments, the plurality of ligands 2 comprise a first ligand and a second ligand, the first ligand and the second ligand are attached to one quantum dot via coordination, the crosslinking group is attached to the first ligand, and the crosslinking group is configured to undergo a photo-crosslinking reaction with a reactive group of the second ligand.

The plurality of ligands 2 may further comprise ligands 2 other than the first ligand and the second ligand, in which one or more crosslinking groups may be attached to the first ligand, and the second ligand may comprise at least one reactive group. Under the desired reaction conditions for the crosslinking reaction, the crosslinking groups in the first ligand may link with the reactive group of the second ligand. For example, the quantum dot 1A may link with the quantum dot 1B by connecting the crosslinking group A of the first ligand attached to the quantum dot 1A to the reactive group B of the second ligand attached to the quantum dot 1B. The quantum dot 1A may link with the quantum dot 1B by connecting the reactive group B attached to the second ligand of the quantum dot 1A to the crosslinking group A of the first ligand attached to the quantum dot 1B.

In other embodiments, the plurality of quantum dots 1 comprises a first quantum dot and a second quantum dot, the plurality of ligands 2 comprises a first ligand and a second ligand, the first ligand is attached to the first quantum dot via coordination, the second ligand is attached to the second quantum dot via coordination, one crosslinking group is attached to the first ligand, and the crosslinking group is configured to undergo a photocrosslinking reaction with the second ligand.

The plurality of ligands 2 may further comprise other ligands 2 than the first ligand and the second ligand, and the first quantum dot and the second quantum dot both may link with same or different other ligands 2. A crosslinking group is attached to the first ligand, and the crosslinking group is configured to undergo a photocross-linking reaction with the second ligand, making it possible to connect the first quantum dot to the second quantum dot by the photo-crosslinking reaction between the crosslinking group and the second ligand, while avoiding the photo-crosslinking reaction between the cross-linking group and the reactive group connected to the same quantum dot 1.

For example, the first quantum dot A may be connected to the second quantum dot B by connecting the crosslinking group A of the first ligand attached to the first quantum dot A to the reactive group B of the second ligand attached to the second quantum dot B.

Those skilled in the art may determine quantum dots 1 based on the bandgap of the quantum dots, and crosslinking reactants 2 based on the frontier molecular orbital energy level of the crosslinking reactants.

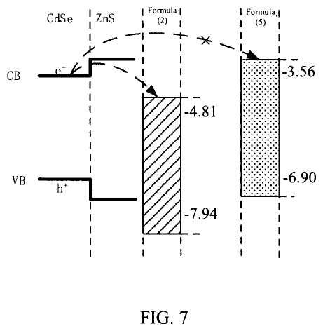

With reference to FIG. 7, as an example, the crosslinking molecule as shown in Formula (2) has a LUMO energy level of −4.81 cV, and when CdSe@ZnS is used a quantum dot 1, the quantum dot 1 has a conduction band of −4.0 eV. The crosslinking molecule as shown in Formula (2) is selected to be mixed with the quantum dot 1 to form a quantum dot luminescent material A, and the quantum dot luminescent material A is employed to prepare a quantum dot luminescent layer. The crosslinking molecule as shown in Formula (5) has a LUMO energy level of −3.56 eV. The crosslinking molecule as shown in Formula (5) is selected to be mixed with the quantum dot 1 to form a quantum dot luminescent material B, and the quantum dot luminescent material B is employed to prepare a quantum dot luminescent layer.

Luminescence testing was performed on a display device having a quantum dot luminescent layer A and a display device having a quantum dot luminescent layer B, and the results shown in Table 1 were obtained. By setting the lowest unoccupied molecular orbital LUMO energy level of the crosslinking reactant to be located outside the band gap of quantum dots, or the highest occupied molecular orbital HOMO energy level of the crosslinking reactant to be located outside the band gap of the quantum dots, and by satisfying at least one of the above two conditions, it is possible, to a certain extent, to reduce or avoid the transfer of photogenerated carriers generated by excitation of the quantum dots to the crosslinking reactant, to reduce a decrease in yield of the photoluminescent quantum, and to improve luminescence performances of the quantum dot luminescent layer prepared from the quantum dot luminescent material. Among them, the function of LUMO is larger than that of HOMO. With reference to FIG. 7, the LOMO energy level of Formula (2) is located within the bandgap of quantum dots, and its HOMO energy level is located outside the bandgap of quantum dots. That is, the LOMO of Formula (2) does not comply with the above conditions, and the HOMO complies with the above conditions. Thus, under the condition, there is a slight drop in its EQE since the function of LUMO is larger than that of HOMO. Assuming that the LUMO and HOMO both do not comply with the above conditions, there would be a significant drop in its EQE. The LOMO energy level of Formula (5) is located outside the band gap of the quantum dots and the HOMO energy level is located inside the band gap of the quantum dots. That is, the LOMO satisfies the above conditions and the HOMO does not satisfies the above conditions. Thus, under the condition, its EQE rises since the LOMO plays a main role.

TABLE 1

| UV wavelengths | Crosslinking molecule | EQE % | L@6V | T95(h) | T95@1K nit(h) |
|---|---|---|---|---|---|
| 365 nm | Before crosslinking | 13.4 | 15750 | 96.7 | 3679 |
| | After crosslinking with Formula (2) | 12.6 | 6693 | 52.9 | 1823 |
| 365 nm | Before crosslinking | 11.2 | 9628 | 198.9 | 4103 |
| | After crosslinking with Formula (5) | 11.7 | 11330 | 191.6 | 4852 |

In the quantum dot luminescence layer A, electrons transfer from the quantum dot to the crosslinking molecule occurs since the LUMO energy level of the crosslinking molecule is smaller than the conduction band energy level of QDs, resulting in quantum dot fluorescence quenching. In the quantum dot luminescence layer B, there is no electron transfer between the quantum dots and the crosslinking molecules since the LUMO energy level of the crosslinking molecules is larger than the conduction band energy level of QDs, which avoids a decrease in luminescence of the quantum dot luminescence layer caused by the transfer of electrons to the crosslinking molecules. From the experimental results, it can be seen that the luminous efficiency of the quantum dot luminescent layer A is lower than that of the quantum dot luminescent layer B when the quantum dot luminescent layer A and the quantum dot luminescent layer B are used for luminescent display. When the same nits of light waves are continuously emitted, a decrease in service life of the quantum dot light emitting layer A is higher than a decrease in service life of the quantum dot light emitting layer B.

In some embodiments, the quantum dots 1 are one of red light quantum dots 1, green light quantum dots 1, and blue light quantum dots 1.

The quantum dot luminescent material may comprise only quantum dots 1 for emitting light of one color. In the case where the quantum dots 1 in the quantum dot luminescent material are red light quantum dots 1, the quantum dot luminescent layer prepared from the quantum dot luminescent material is used to generate red light by excitation. In the case where the quantum dots 1 in the quantum dot luminescent material are green light quantum dots 1, the quantum dot luminescent layer prepared from the quantum dot luminescent material is used to generate green light by excitation. In the case where the quantum dots 1 in the quantum dot luminescent material are blue light quantum dots 1, the quantum dot luminescent layer prepared from the quantum dot luminescent material is used to generate blue light by excitation.

A patterned red luminescent layer, a patterned green luminescent layer, and a patterned blue luminescent layer may be prepared by the quantum dot luminescent material having red light quantum dots 1, the quantum dot luminescent material having green light quantum dots 1, and the quantum dot luminescent material having blue light quantum dots 1, respectively, and the patterned red luminescent layer, green luminescent layer, and blue luminescent layer are cooperated together for luminescent displays of different colors.

In some embodiments, the quantum dot luminescent material has a mass ratio of the quantum dots 1 and the crosslinking reactants 3 in the range of 1% to 10%.

Too few crosslinking reactant 3 in the quantum dot luminescent material will result in all or part of the material layer located in the target area of the patterned quantum dot luminescent layer being removed along with the material layer located in the non-target area in the process of development. By setting the mass ratio of the quantum dots 1 and the crosslinking reactants 3 to be in the range of 1% to 10%, it is possible to enable the material layer located in the target region to be retained in the process of development.

In some embodiments, the quantum dots 1 are red light quantum dots 1, and a mass ratio of the red light quantum dots 1 and the crosslinking reactants 3 in the quantum dot luminescent material is in the range of 1% to 6%.

In some embodiments, the quantum dots 1 are green light quantum dots 1, and a mass ratio of the green light quantum dots 1 and the crosslinking reactants 3 in the quantum dot luminescent material is in the range of 1% to 8%.

In some embodiments, the quantum dots 1 are blue light quantum dots 1, and a mass ratio of the blue light quantum dots 1 and the crosslinking reactants 3 in the quantum dot luminescent material is in the range of 1% to 8%.

As the quantum dots 1 emitting different colors are different in size, the quantum dot luminescent material having quantum dots 1 of different colors exhibits different film retention after development treatment even when the same mass ratio of the quantum dots 1 and the cross-linking reactants 3 is adopted. By setting the mass ratio of the red light quantum dots 1 and the crosslinking reactant 3 to be in the range of 1% to 6%, the mass ratio of the green light quantum dots 1 and the crosslinking reactant 3 to be in the range of 1% to 8%, and the mass ratio of the blue light quantum dots 1 and the crosslinking reactant 3 to be in the range of 1% to 8%, it is possible to enable the quantum dot luminescent material disposed in the target region to exhibit a film retention rate of 100% after the development treatment.

A second aspect of the present application provides a method of preparing a display device comprising the following steps:
S100, forming a first material layer on a first interface layer from the quantum dot luminescent material as provided in the first aspect, the first material layer comprising a first region and a second region;
S200, exposing the first region to cause the crosslinking reactant to undergo a photocrosslinking reaction to connect at least two quantum dots;
S300, developing the first material layer to remove a portion of the first material layer disposed in the second region, thereby obtaining a patterned first quantum dot luminescent layer.

The first interfacial layer may be a carrier transport layer. The first interfacial layer may also be a prepared patterned quantum dot luminescent layer, and the prepared quantum dot luminescent layer may emit the color light that is inconsistent with the color light emitted by the first quantum dot luminescent layer prepared in S300 so that a superimposed-color light may be obtained when the two layers emit lights together.

A mask plate having a predetermined graphic opening may be used, the mask plate is set on one side of the first material layer including a first region and a second region, a light of a first wavelength is used to expose the first region through the mask plate, and under the action of the light of the first wavelength, a photo-crosslinking reaction occurs through the cross-linking reactants, and the quantum dots disposed in the first region form a lattice structure, so that the stability of the quantum dots disposed in the first region is higher than the stability of the quantum dots disposed in the second region.

The first material layer is developed using a developer that can dissolve the quantum dot luminescent material, and the developer removes a portion of the first material layer disposed in the second region while retaining a portion of the first material layer disposed in the first region, so as to obtain a patterned first quantum dot luminescent layer that is consistent with a pattern of the predetermined patterned opening.

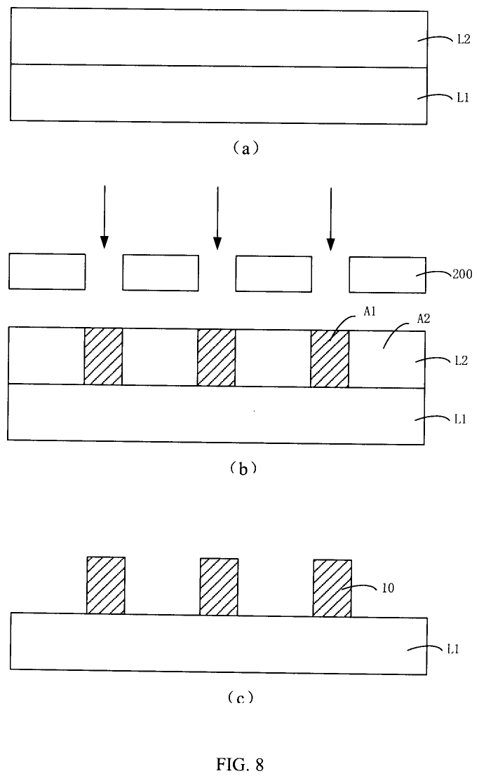

As an example, with reference to FIG. 8(a), the quantum dot luminescent material is formed into a first material layer L2 on a first interface layer L1; with reference to FIG. 8(b), a first region A1 is subjected to an exposure process through a mask plate 200 having a predetermined patterned opening; and with reference to FIG. 8(c), the first material layer L2 is subjected to a development process in which a portion of the first material layer L2 disposed in a second region A2 is removed, thereby obtaining a patterned first quantum dot luminescent layer 10.

By forming the quantum dot luminescent layer by the photolithographic process, the embodiments of the present application can improve uniformity of the quantum dot luminescent layer in morphology and thickness, and improve fineness of the patterned first quantum dot luminescent layer, thereby improving resolution of the display device prepared from the first quantum dot luminescent layer and improving performances of the display device. By adopting the quantum dot luminescent material provided in the first aspect, the patterned quantum dot luminescent layer can, to a certain extent, reduce or avoid the transfer of photogenerated carriers generated by excitation of the quantum dots 1 to the crosslinked reactants 3, reduce a decrease in photoluminescent quanta yield, and improve luminescent performance of the quantum dot luminescent layer.

In some embodiments, the method further comprises:
S400, forming a second material layer on the first interface layer from the quantum dot luminescent material as provided in the first aspect, wherein the second material layer comprises quantum dots configured to emit a second color light, and the first material layer comprises quantum dots configured to emit a first color light, and the second material layer comprises a third region and a fourth region;
S500, exposing the third region to cause the crosslinking reactant to undergo a photocrosslinking reaction to connect at least two quantum dots;
S600, developing the second material layer to remove a portion of the second material layer disposed in the fourth region, thereby obtaining a patterned second quantum dot luminescent layer, the first quantum dot luminescent layer and the second quantum dot luminescent layer being parallel-disposed on the first interface layer.

The difference between S100 and of S400 is that the quantum dot luminescent material employed in S100 has quantum dots for emitting a first color light, and the quantum dot luminescent material employed in S400 has quantum dots for emitting a second color light, such that the first quantum dot luminescent layer may be excited to emit the first color light, and the second quantum dot luminescent layer may be excited to emit the second color light. The patterned first quantum dot luminescent layer and second quantum dot luminescent layer are both provided on the first interface layer, and different patterns can be displayed by exciting different regions of the first quantum dot luminescent layer and the second quantum dot luminescent layer to emit light.

In S500, the third region may be all or part of the second region. That is, after developing the first material layer, the first material layer disposed in the second region is removed, and then the second material layer with a grid structure is formed in all or part of the second region through S500. With reference to S400-S600 for a plurality of repetitions, a plurality of quantum dot luminescent layers are provided on the first interfacial layer, and the quantum dot luminescent layers each can emit different colored light under the effect of the excitation light.

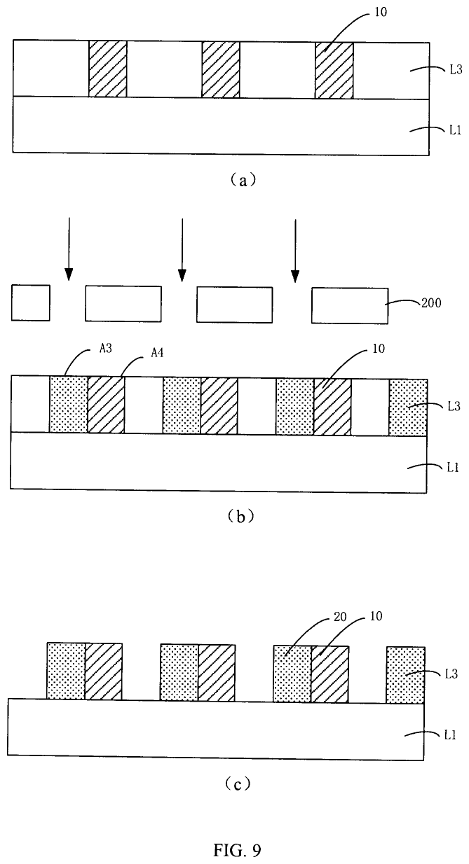

As an example, with reference to FIG. 9(a), the quantum dot luminescent material is formed into a second material layer L3 on a portion of the first interface layer L1 corresponding to the second region; with reference to FIG. 9(b), a mask plate 200 having a predetermined patterned opening is used to perform an exposure treatment on the third region A3; and with reference to FIG. 9(c), the second material layer L3 is subjected to a development treatment to remove a portion of the second material layer L3 located in the fourth region A4 to obtain the patterned second quantum dot luminescent layer 20.

A third aspect of the present application provides a quantum dot film comprising a first quantum dot luminescent layer prepared as in the quantum dot patterning method provided in the second aspect and a second quantum dot luminescent layer prepared as in the quantum dot patterning method provided in the second aspect, the first quantum dot luminescent layer being configured to emit a first color light and the second quantum dot luminescent layer being configured to emit a second color light.

The quantum film may further comprise a third quantum dot luminescent layer prepared by the quantum dot patterning method as provided in the second aspect, the third quantum dot luminescent layer being configured to emit a third color light. The first color light, the second color light and the third color light may be selected from red light, green light and blue light, respectively.

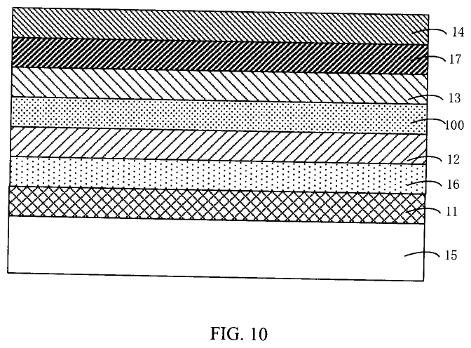

With reference to FIG. 10, a fourth aspect of the present application provides a display device, the display device comprising the quantum dot film 100 as provided in the third aspect.

The display device comprises the quantum dot film 100 of any of the above embodiments. As the display device adopts all of the technical solutions of all of the above embodiments, it has at least all of the beneficial effects brought about by the technical solutions of the above embodiments, which will not be repeated herein.

The display device may be any device having a display function. For example, it may be a mobile phone, a tablet computer, a laptop computer, a palmtop computer, an in-car electronic device, a wearable device, an ultra-mobile personal computer (UMPC), a netbook, or a personal digital assistant (abbreviated as PDA) and other mobile devices, and may also be a personal computer (abbreviated as PC), a television (abbreviated as TV), a teller machine, or a kiosk and other non-mobile devices.

In some embodiments, the display device comprises a bottom electrode 11, a first carrier transmission layer 12, a second carrier transmission layer 13, and a top electrode 14 in which the first carrier transmission layer 12 is disposed on a side of the bottom electrode 11; the second carrier transmission layer 13 is disposed on a side of the first carrier transmission layer 12 away from the bottom electrode 11; the top electrode 14 is disposed on a side of the second carrier transmission layer 13 away from the bottom electrode 11; and the quantum dot film 100 is provided between the first carrier transport layer 12 and the second carrier transport layer 13.

The display device may further comprise a substrate 15, in which the bottom electrode 11 is provided on the substrate 15. The substrate 15 may be a rigid glass or a flexible PI film (Polyimide Film).

The display device of embodiments of the present application may be a display device of an orthogonal quantum dot luminescent diode, with the bottom electrode 11 being an anode, the first carrier transport layer 12 being a hole transport layer, the second carrier transport layer 13 being an electron transport layer, and the top electrode 14 being a cathode. It should be noted that in other embodiments, the display device may also be a display device of an inverted quantum dot luminescent diode, with the bottom electrode 11 being a cathode, the first carrier transport layer 12 being an electron transport layer, the second carrier transport layer 13 being a hole transport layer, and the top electrode 14 being an anode.

When electrons and holes enter the quantum dot luminescent layer through the electron transport layer and the hole transport layer, respectively, the quantum dots are excited by exciton energy and emit light. In addition, due to the existence of a quantum confinement effect in the quantum dots, the wavelength of the light emitted by the electron-hole complex will vary with the size of the quantum dots, and the quantum dots of different sizes will emit light of different colors. For example, the quantum dot luminescent layer may include blue light quantum dots, green light quantum dots, or red light quantum dots, and the blue light quantum dots may be ZnCdS, ZnCdS/ZnS, ZnSe/ZnS, and the like; the green light quantum dots may be ZnCdSeS, ZnCdSeS/ZnS, and the like; and the red light quantum dots may be CdSe/CdS, CdSe/ZnSe, ZnCdSeS/ZnS, and the like.

The material for the anode can be high-work function metals and metal oxides, such as indium tin oxide, indium zinc oxide, or elemental gold. The materials for the hole transport layer are Poly-TPD (polytriphenylamine), TFB (1,2,4,5-tetra(trifluoromethyl)benzene), PVK (polyvinyl carbazole), NPB (N,N′-diphenyl-N,N′-(1-naphthyl)-1,1′-biphenyl-4,4′-diamine), TAPC (4,4′-cyclohexylidene di [N,N-di(4-methyl phenyl) aniline]), TCTA (4,4′,4″-tris(carbazol-9-yl)triphenylamine), mCP (2,6-dimethoxy phenol), CBP (4,4′-bis(9-carbazole) biphenyl), mCBP (3,3-di(carbazolyl) biphenyl), CDBP (4,4′-bis(9-carbazolyl)-2,2′-dimethylbiphenyl), NiO, Cu₂O, or CuSCN. The materials for the electron transport layer are ZnO, SnO₂, ZnMgO, ZnAJO, ZnGaO, or TiO2. The material for the cathode can be low-work function metals or their alloys, such as Al, Ag, or Mg—Ag alloys.

The display device may further comprise a first carrier injection layer 16, which is disposed between the bottom electrode 11 and the first carrier transport layer 12.

When the first carrier transport layer 12 is a hole transport layer, the first carrier injection layer 16 is a hole injection layer. The hole injection layer can increase the concentration of holes and improve luminous efficiency. When the first carrier transport layer 12 is an electron transport layer, then the first carrier injection layer 16 is an electron injection layer. The electron injection layer can increase the concentration of electrons and improve luminous efficiency.

Optionally, the display device may further include a second carrier injection layer 17, which is disposed between the second carrier transport layer 13 and the top electrode 14.

Taking the display device of the present application as an example, which is a display device of an upright quantum dot light-emitting diode, the first carrier injection layer 16 is a hole injection layer, the first carrier transport layer 12 is a hole transport layer, the second carrier transport layer 13 is an electron transport layer, and the second carrier injection layer 17 is an electron injection layer. Through the coordination of the hole transport layer, hole injection layer, electron transport layer, and electron injection layer, the luminous efficiency of the display device can be further improved.

The above is only a specific embodiment of this application, but the scope of protection of the present application is not limited to this. Any technician skilled in the art can easily think of various equivalent modifications or substitutions within the technical scope disclosed by this application. These modifications or substitutions should be encompassed by the scope of protection of this application. Therefore, the scope of protection of this application should be based on the scope of protection of the claims.

What is claimed is:

1. A quantum dot luminescent material comprising
a plurality of quantum dots;
a plurality of ligands attached to the quantum dots;
a plurality of crosslinking reactants configured to undergo a crosslinking reaction to connect at least two of the quantum dots and the crosslinking reactants being a plurality of crosslinking molecules or a plurality of crosslinking groups;
wherein the quantum dots and the crosslinking reactants satisfy at least one of Condition (1), Condition (2), or a combination thereof,
Condition (1): the crosslinking reactants have a lowest unoccupied molecular orbital (LUMO) energy level that is located outside a bandgap of the quantum dots; and
Condition (2): the crosslinking reactants have a highest occupied molecular orbital (HOMO) energy level that is located outside the bandgap of the quantum dots.

2. The quantum dot luminescent material according to claim 1, wherein the quantum dots have a valence band greater than the HOMO energy level of the crosslinking reactants, and a difference in energy level between the valence band of the quantum dots and the HOMO energy level of the crosslinking reactants is greater than 0.2 eV.

3. The quantum dot luminescent material according to claim 1, wherein the quantum dots have a conduction band less than the LUMO energy level of the crosslinking reactants, and a difference in energy level between the conduction band of the quantum dots and the LUMO energy level of the crosslinking reactants is greater than 0.2 eV.

4. The quantum dot luminescent material according to claim 1, wherein the crosslinking reactants are the plurality of crosslinking molecules, each of the crosslinking molecule comprises at least two photosensitive groups, and the photosensitive groups are configured to undergo a photo-crosslinking reaction with a reactive group of the ligands.

5. The quantum dot luminescent material according to claim 4, wherein n photosensitive groups are provided for one crosslinking molecule in which 2≤n≤6.

6. The quantum dot luminescent material according to claim 4, wherein each of the crosslinking molecule has a structure shown in Formula (1):
P—R—P (1),
wherein P is a photosensitive group; and
R is an aliphatic group, a heterocyclic group or an aromatic group comprising a benzene ring structure; or
R comprises at least one halogen element; or
R comprises at least one alkali metal element.

7. The quantum dot luminescent material according to claim 4, wherein each of the crosslinking molecule has one of the structure shown in formula (2), the structure shown in formula (3), the structure shown in formula (4), or the structure shown in formula (5) below:

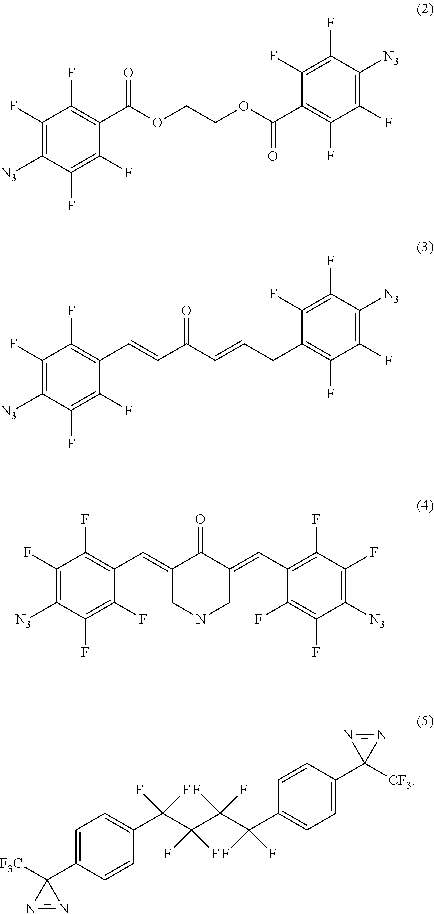 [SMILES: [N-]=[N+]=Nc1c(F)c(F)c(C(=O)OCCOC(=O)c2c(F)c(F)c(N=[N+]=[N-])c(F)c2F)c(F)c1F ; [N-]=[N+]=Nc1c(F)c(F)c(/C=C/C(=O)/C=C/Cc2c(F)c(F)c(N=[N+]=[N-])c(F)c2F)c(F)c1F ; [N-]=[N+]=Nc1c(F)c(F)c(/C=C2\CNC/C(=C\c3c(F)c(F)c(N=[N+]=[N-])c(F)c3F)C2=O)c(F)c1F ; FC(F)(F)C1(c2ccc(C(F)(F)C(F)(F)C(F)(F)C(F)(F)c3ccc(C4(C(F)(F)F)N=N4)cc3)cc2)N=N1]

8. The quantum dot luminescent material according to claim 1, wherein the crosslinking reactants are a plurality of crosslinking groups attached to the ligands, and the crosslinking group is configured to undergo a photo-crosslinking reaction with a reactive group of the ligands.

9. The quantum dot luminescent material according to claim 8, wherein the plurality of ligands comprise a first ligand and a second ligand, the first ligand and the second ligand are attached to one quantum dot via coordination, the crosslinking group is attached to the first ligand, and the crosslinking group is configured to undergo a photo-crosslinking reaction with a reactive group of the second ligand.

10. The quantum dot luminescent material according to claim 8, wherein the plurality of quantum dots comprise a first quantum dot and a second quantum dot, the plurality of ligands comprise a first ligand and a second ligand, the first ligand is attached to the first quantum dot via coordination, the second ligand is attached to the second quantum dot via coordination, the crosslinking group is attached to the first ligand, and the crosslinking group is configured to undergo a photo-crosslinking reaction with the second ligand.

11. The quantum dot luminescent material according to claim 1, wherein the quantum dots are any one of red light quantum dots, green light quantum dots, and blue light quantum dots.

12. The quantum dot luminescent material according to claim 11, wherein a mass ratio of the quantum dots and the crosslinking reactants is in the range of 1% to 10%.

13. The quantum dot luminescent material according to claim 11, wherein
the quantum dots are red light quantum dots, and a mass ratio of the red light quantum dots and the crosslinking reactants is in the range of 1% to 6%; or
the quantum dots are green light quantum dots, and a mass ratio of the green light quantum dots and the crosslinking reactants is in the range of 1% to 8%; or
the quantum dots are blue light quantum dots, and a mass ratio of the blue light quantum dots and the crosslinking reactants is in the range of 1% to 8%.

14. A quantum dot patterning method comprising the steps of:
forming a first material layer on a first interface layer with the quantum dot luminescent material as claimed in claim 1, the first material layer comprising a first region and a second region;
exposing the first region to cause the crosslinking reactant to undergo a photocrosslinking reaction to connect at least two quantum dots; and
developing the first material layer to remove a portion of the first material layer disposed in the second region, thereby obtaining a patterned first quantum dot luminescent layer.

15. The method according to claim 14, wherein it further comprises the steps of:
forming a second material layer on the first interface layer with the quantum dot luminescent material, wherein the second material layer comprises quantum dots configured to emit a second color light, and the first material layer comprises quantum dots configured to emit a first color light, and the second material layer comprises a third region and a fourth region;
exposing the third region to cause the crosslinking reactant to undergo a photocrosslinking reaction to connect at least two quantum dots; and
developing the second material layer to remove a portion of the second material layer disposed in the fourth region, thereby obtaining a patterned second quantum dot luminescent layer, the first quantum dot luminescent layer and the second quantum dot luminescent layer being parallel-disposed on the first interface layer.

16. A quantum dot film comprising a first quantum dot luminescent layer and a second quantum dot luminescent layer, the first quantum dot luminescent layer comprising the quantum dot luminescent material as claimed in claim 1 and configured to emit a first color light, and the second quantum dot luminescent layer configured to emit a second color light.

17. A display device comprising a light emitting device having the quantum dot film as claimed in claim 16.

18. The display device according to claim 17, wherein the display device comprises
a bottom electrode;
a first carrier transport layer, disposed on a side of the bottom electrode;
a second carrier transport layer, disposed on a side of the first carrier transport layer away from the bottom electrode;
a top electrode, disposed on the side of the second carrier transport layer away from the bottom electrode; and
the quantum dot film, disposed between the first carrier transport layer and the second carrier transport layer.
